(19) United States
(12) Patent Application Publication
(10) Pub. No.: US 2022/0052674 A1
(43) Pub. Date: Feb. 17, 2022

(54) HIGH SPEED LEVEL SHIFTER

(71) Applicant: Silicon Works Co., Ltd., Daejeon (KR)

(72) Inventor: Jang Hyun YOON, Daejeon (KR)

(73) Assignee: Silicon Works Co., Ltd., Daejeon (KR)

(21) Appl. No.: 17/402,353

(22) Filed: Aug. 13, 2021

(30) Foreign Application Priority Data
Aug. 14, 2020 (KR) 10-2020-0102451

(51) Int. Cl. H03K 3/356

(52) U.S. Cl. CPC H03K 3/356104

(57) ABSTRACT

Disclosed is a high speed level shifter which converts a low voltage into a high voltage. The high speed level shifter includes an output circuit configured to output an output signal of a high voltage range in response to an input signal of a low voltage range; an input circuit operated in the low voltage range, and configured to control output of the output signal through an output terminal in response to the input signal; and a connection circuit configured to drop a voltage applied to the input circuit from the output circuit.

### BACKGROUND

### 1. Technical Field

Various embodiments generally relate to a high speed level shifter, and more particularly, to a high speed level shifter which converts a low voltage into a high voltage.

### 2. Related Art

Recently, a home appliance is configured to include a micro control unit for electronic control.

The micro control unit is configured to electrically interface with various external components of the home appliance and perform necessary control. For example, the micro control unit is configured to receive a signal from a signal source such as a sensor, perform digital signal processing on the received signal, and output a digital signal processing result to the outside.

The micro control unit may be designed to use a low voltage for low power consumption.

A signal by digital signal processing in the micro control unit may be defined as a logic signal, and the logic signal may be driven using a low voltage. For example, the logic signal may have a low voltage range that uses a driving voltage of 1.2V as a low voltage.

Unlike the micro control unit, an external part which electrically interfaces with the micro control unit may be configured to operate using a high voltage. The high voltage may be exemplified as 5V, and the external part may be configured to receive a signal of a high voltage range using a driving voltage of 5V.

For this reason, in order for interfacing with the external part, the micro control unit needs to convert the logic signal from the low voltage range to the high voltage range and output an output signal.

To this end, a level shifter capable of converting the logic signal from the low voltage range to the high voltage range may be configured in the micro control unit.

In general, the level shifter outputs an output signal having an amount of current proportional to the current of an input signal, and is configured using high voltage transistors which operate in the high voltage range.

The level shifter requires the input signal which has a sufficient amount of input current to drive the high voltage transistors for a normal output and a high speed operation.

The logic signal in the micro control unit has the low voltage range as described above. Thus, the logic signal may not have a sufficient amount of current for a normal output and a high speed operation of the level shifter.

Therefore, the level shifter may have a problem in that the level shifter is likely to malfunction by the input of the logic signal of the low voltage range or a high speed operation is difficult to perform and an operating speed is limited, by an insufficient amount of current of the logic signal.

### SUMMARY

Various embodiments are directed to a high speed level shifter which can prevent a malfunction and is capable of a high speed operation when an electronic device such as a micro control unit outputs an output signal of a high voltage range in response to a logic signal of a low voltage range.

Also, various embodiments are directed to a high speed level shifter which, by using a low power transistor, can prevent a malfunction and is capable of a high speed operation when outputting an output signal of a high voltage range by using an input signal of a low voltage range, and which can prevent the low power transistor from being damaged by a high voltage.

In an embodiment, a high speed level shifter may include: an output circuit configured to output an output signal of a high voltage range in response to an input signal of a low voltage range; an input circuit configured to control output of the output signal in response to the input signal; and a connection circuit connecting the output circuit and the input circuit, wherein the output circuit is operated in the high voltage range, wherein the input circuit is operated in the low voltage range, and wherein the connection circuit drops a voltage applied to the input circuit from the output circuit.

The high speed level shifter according to the embodiments of the present disclosure may prevent a malfunction and is capable of a high speed operation for outputting an output signal of a high voltage range, when an electronic device such as a micro control unit outputs the output signal of the high voltage range in response to an input signal of a low voltage range.

Further, the high speed level shifter according to the embodiments of the present disclosure may prevent a low voltage transistor, configured to receive the input signal of a low voltage range, from being damaged and may protect a drain voltage of the low voltage transistor from a high voltage, which makes it possible to achieve improved reliability and secure operational stability.

Therefore, a display driving device using the high speed level shifter according to the embodiments of the present disclosure may drive, with low power, each output channel in which an output buffer is configured, which makes it possible to reduce power consumption in the unit of a chip.

### BRIEF DESCRIPTION OF THE DRAWINGS

FIG. 1 is a circuit diagram illustrating a high speed level shifter in accordance with an embodiment of the present disclosure.

FIG. 2 is a circuit diagram illustrating a high speed level shifter in accordance with another embodiment of the present disclosure.

FIG. 3 is a circuit diagram illustrating a high speed level shifter in accordance with still another embodiment of the present disclosure.

### DETAILED DESCRIPTION

The present disclosure discloses a high speed level shifter configured in an electronic device, such as a micro control unit, which performs digital signal processing.

The high speed level shifter according to the present disclosure is embodied to output an output signal of a high voltage range in response to an input signal of a low voltage range.

An embodiment of the present disclosure may use a low voltage transistor which operates in a low voltage range to sufficiently recognize, without a malfunction, an input signal of the low voltage range with a small amount of current.

Further, an embodiment of the present disclosure may include a configuration for preventing a low voltage transistor from being damaged by an output driving voltage of a high voltage range for driving an output signal. Also, an embodiment of the present disclosure may include a configuration for implementing a clamping function for protecting a drain voltage of a low voltage transistor.

For description of an embodiment of the present disclosure, a low voltage range may be exemplified as 0V to 1.2V, and a driving voltage of the low voltage range may be understood as 1.2V. The driving voltage of the low voltage range is referred to as an input driving voltage in the description of the embodiment. A transistor which operates in the low voltage range is referred to as a low voltage transistor.

For the description of the embodiment of the present disclosure, a high voltage range may be exemplified as 0V to 5V, and a driving voltage of the high voltage range may be understood as 5V. The driving voltage of the high voltage range is referred to as an output driving voltage in the description of the embodiment. A transistor which operates in the high voltage range is referred to as a high voltage transistor.

For the description of the embodiment of the present disclosure, a medium voltage range may be exemplified as 0V to 3V, and a transistor which operates in the medium voltage range is referred to as a medium voltage transistor.

Also, for the description of the embodiment of the present disclosure, a threshold voltage of the low voltage transistor may be exemplified as having a level of 0.2V to 0.3V, and a threshold voltage of the high voltage transistor may be exemplified as having a level of 0.6V.

The medium voltage transistor according to the embodiment of the present disclosure may use a transistor whose threshold voltage has a level of substantially 0V and which acts as a load dividing the output driving voltage of 5V into 3V. To this end, the medium voltage transistor may use, for example, a native transistor.

In addition, for the description of the embodiment of the present disclosure, a ground voltage for the low voltage range and the high voltage range may be exemplified as 0V, but may be differently set according to a manufacturer's intention.

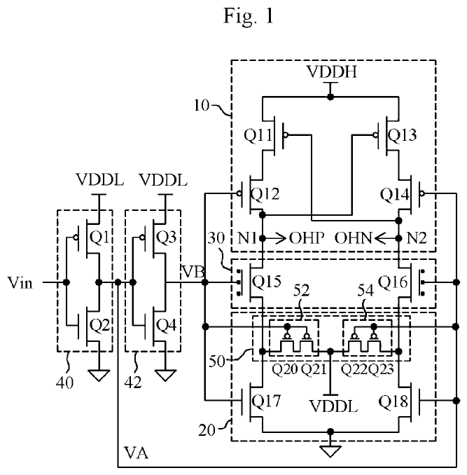

Referring to FIG. 1, a high speed level shifter in accordance with an embodiment of the present disclosure is configured to include an output circuit 10, an input circuit 20 and a connection circuit 30.

The high speed level shifter in accordance with the embodiment of the present disclosure is configured to receive an inverted input signal VA and a non-inverted input signal VB which are provided through two stages of inverters 40 and 42 connected in series.

The inverter 40 is configured to include a PMOS transistor Q1 and an NMOS transistor Q2 which have a common drain. An input driving voltage VDDL of a low voltage range is applied to a source of the PMOS transistor Q1, and a ground voltage of the low voltage range is applied to a source of the NMOS transistor Q2. The PMOS transistor Q1 and the NMOS transistor Q2 of the inverter 40 are low voltage transistors, receive in common an input signal Vin, and output the inverted input signal VA through the common drain. The input signal Vin may be understood as a logic signal of a micro control unit, and the inverter 40 outputs the inverted input signal VA of the low voltage range by inverting the input signal Vin of the low voltage range.

The inverter 42 is configured to include a PMOS transistor Q3 and an NMOS transistor Q4 which have a common drain. The input driving voltage VDDL of the low voltage range is applied to a source of the PMOS transistor Q3, and the ground voltage of the low voltage range is applied to a source of the NMOS transistor Q4. The PMOS transistor Q3 and the NMOS transistor Q4 of the inverter 42 are low voltage transistors, receive in common an output of the inverter 40, that is, the inverted input signal VA, and output the non-inverted input signal VB through the common drain. That is to say, the inverter 42 outputs the non-inverted input signal VB of a low voltage by inverting the inverted input signal VA of a low voltage.

The inverted input signal VA and the non-inverted input signal VB outputted from the inverters 40 and 42 are used to drive the high speed level shifter.

Referring to FIG. 1, the inverted input signal VA and the non-inverted input signal VB are provided to the output circuit 10, the input circuit 20 and the connection circuit 30.

The output circuit 10 operates in a high voltage range, and is configured to output an output signal of the high voltage range through an output terminal in response to an input signal of a low voltage range.

In more detail, the output circuit 10 is configured to include PMOS transistors Q11, Q12, Q13 and Q14 as high voltage transistors and an output terminal. The output terminal is configured to include a first output terminal N1 and a second output terminal N2 which are configured in parallel. The first output terminal N1 may be understood as a node or a terminal which outputs a first output signal OHP, and the second output terminal N2 may be understood as a node or a terminal which outputs a second output signal OHN.

An output driving voltage VDDH is applied to sources of the PMOS transistors Q11 and Q13, the PMOS transistor Q12 is configured to receive the output driving voltage VDDH through the PMOS transistor Q11, the PMOS transistor Q14 is configured to receive the output driving voltage VDDH through the PMOS transistor Q13, a drain of the PMOS transistor Q12 is connected to the first output terminal N1 which outputs the first output signal OHP, and a drain of the PMOS transistor Q14 is connected to the second output terminal N2 which outputs the second output signal OHN.

A gate of the PMOS transistor Q11 is connected to the second output terminal N2, that is, the drain of the PMOS transistor Q14, and a gate of the PMOS transistor Q13 is connected to the first output terminal N1, that is, the drain of the PMOS transistor Q12. The PMOS transistor Q12 is configured such that the non-inverted input signal VB is applied to the gate thereof, and the PMOS transistor Q14 is configured such that the inverted input signal VA is applied to the gate thereof.

When the non-inverted input signal VB of a low level is inputted, the PMOS transistor Q12 is turned on, and the output circuit 10 outputs, as the first output signal OHP, the output driving voltage VDDH transferred through the PMOS transistor Q11, the PMOS transistor Q12 and the first output terminal N1. At this time, the PMOS transistor Q11 maintains turn-on by the second output signal OHN of the second output terminal N2 which has a low level. When the non-inverted input signal VB of a high level is inputted, the PMOS transistor Q12 is turned off, and the level of the first output terminal N1 of the output circuit 10 is controlled to a low level by the input circuit 20. At this time, the PMOS transistor Q11 is turned off by the second output signal OHN of the second output terminal N2 which has a high level.

When the inverted input signal VA of a low level is inputted, the PMOS transistor Q14 is turned on, and the output circuit 10 outputs, as the second output signal OHN, the output driving voltage VDDH transferred through the PMOS transistor Q13, the PMOS transistor Q14 and the second output terminal N2. At this time, the PMOS transistor Q13 maintains turn-on by the first output signal OHP of the first output terminal N1 which has a low level. When the inverted input signal VA of a high level is inputted, the PMOS transistor Q14 is turned off, and the level of the second output terminal N2 of the output circuit 10 is controlled to a low level by the input circuit 20. At this time, the PMOS transistor Q13 is turned off by the first output signal OHP of the first output terminal N1 which has a high level.

In other words, the output circuit 10 outputs the first output signal OHP corresponding to the non-inverted input signal VB through the first output terminal N1, and outputs the second output signal OHN corresponding to the inverted input signal VA through the second output terminal N2.

In the above configuration, the PMOS transistor Q12 may be understood as operating in the high voltage range and selectively transferring the output driving voltage VDDH to the first output terminal N1 by the non-inverted input signal VB of the gate thereof, and the PMOS transistor Q14 may be understood as operating in the high voltage range and selectively transferring the output driving voltage VDDH to the second output terminal N2 by the inverted input signal VA of the gate thereof.

The connection circuit 30 is configured to connect the first output terminal N1 and the second output terminal N2 of the output circuit 10 to the input circuit 20, and is configured to drop a voltage applied from each of the first output terminal N1 and the second output terminal N2 to the input circuit 20.

To this end, the connection circuit 30 may be configured to selectively perform the connection of the first output terminal N1 and the second output terminal N2 to the input circuit 20 in response to an input signal, that is, the inverted input signal VA and the non-inverted input signal VB.

In more detail, the connection circuit 30 may be configured to include a connection transistor Q15 which connects the first output terminal N1 of the output circuit 10, that is, the drain of the PMOS transistor Q12, to the input circuit 20 and a connection transistor Q16 which connects the second output terminal N2 of the output circuit 10, that is, the drain of the PMOS transistor Q14, to the input circuit 20. The connection transistor Q15 may be configured by an NMOS transistor, and may be configured such that a source thereof is connected to a drain of an NMOS transistor Q17 of the input circuit 20 to be described below. The connection transistor Q16 may be configured by an NMOS transistor, and may be configured such that a source thereof is connected to a drain of an NMOS transistor Q18 of the input circuit 20 to be described below.

In the embodiment of FIG. 1, the connection transistor Q15 is configured such that the non-inverted input signal VB is applied to a gate thereof, and the connection transistor Q16 is configured such that the inverted input signal VA is applied to a gate thereof. Namely, the connection transistor Q15 is turned on by the non-inverted input signal VB of a high level, and the connection transistor Q16 is turned on by the inverted input signal VA of a high level.

The connection transistors Q15 and Q16 of the connection circuit 30 may be configured by medium voltage transistors. Therefore, the connection circuit 30 may drop a voltage applied from the first output terminal N1 or the second output terminal N2 of the output circuit 10 to the input circuit 20, by a voltage applied between a drain and a source of each of the connection transistors Q15 and Q16 which have characteristics of medium voltage transistors.

A voltage dropping degree of the connection circuit 30 may be determined by physical characteristics of the connection transistors Q15 and Q16 as medium voltage transistors. The connection circuit 30 may have a voltage dropping characteristic such that a voltage applied on the input circuit 20 by the first output signal OHP and the second output signal OHN may have a level included in the low voltage range.

By the above description, it may be understood that the connection transistors Q15 and Q16 of the connection circuit 30 operate in a medium voltage range lower than the high voltage range and higher than the low voltage range. However, if necessary, the connection transistors Q15 and Q16 of the connection circuit 30 may be configured as low voltage transistors according to a manufacturer's intention.

The input circuit 20 operates in the low voltage range, and is configured to control output of an output signal through an output terminal in response to an input signal. That is to say, the input circuit 20 is configured to control output of the first output signal OHP of the first output terminal N1 in response to the non-inverted input signal VB and control output of the second output signal OHN of the second output terminal N2 in response to the inverted input signal VA.

In more detail, the input circuit 20 may include the NMOS transistors Q17 and Q18 which are low voltage transistors. The NMOS transistor Q17 operates in the low voltage range and is to selectively control the first output terminal N1 to a ground level by the non-inverted input signal VB of a gate thereof, and the NMOS transistor Q18 operates in the low voltage range and is to selectively control the second output terminal N2 to the ground level by the inverted input signal VA of a gate thereof.

The NMOS transistor Q17 is configured such that the ground voltage is applied to a source, the non-inverted input signal VB is applied to the gate and the drain is connected to the source of the connection transistor Q15. The NMOS transistor Q18 is configured such that the ground voltage is applied to a source, the inverted input signal VA is applied to the gate and the drain is connected to the source of the connection transistor Q16.

The input circuit 20 may include a clamping circuit 50 which is configured between the drain of the NMOS transistor Q17 and the drain of the NMOS transistor Q18.

The clamping circuit 50 clamps the drain of the NMOS transistor Q17 or the NMOS transistor Q18 to a constant voltage when the NMOS transistor Q17 or the NMOS transistor Q18 is turned off, and is to protect, by the clamping, a drain voltage of the NMOS transistor Q17 or the NMOS transistor Q18. The clamping circuit 50 may be configured to use the input driving voltage VDDL as the constant voltage.

In more detail, the clamping circuit 50 may include a first clamping circuit 52 for protecting the drain voltage of the NMOS transistor Q17 and a second clamping circuit 54 for protecting the drain voltage of the NMOS transistor Q18.

The first clamping circuit 52 is configured to, when the NMOS transistor Q17 is turned off, be turned on in response to the non-inverted input signal VB and thereby provide the input driving voltage VDDL as the constant voltage to the drain of the NMOS transistor Q17. Therefore, the first clamping circuit 52 may protect the drain voltage of the NMOS transistor Q17 such that the NMOS transistor Q17 has the constant voltage even when being turned off. The second clamping circuit 54 is configured to, when the NMOS transistor Q18 is turned off, be turned on in response to the inverted input signal VA and thereby provide the input driving voltage VDDL as the constant voltage to the drain of the NMOS transistor Q18. Therefore, the second clamping circuit 54 may protect the drain voltage of the NMOS transistor Q18 such that the NMOS transistor Q18 has the constant voltage even when being turned off.

The first clamping circuit 52 described above may include at least two PMOS transistors, for example, PMOS transistors Q20 and Q21, which are connected in series. The PMOS transistors Q20 and Q21 have gates to which the non-inverted input signal VB is applied in common, and are connected in series between a terminal to which the constant voltage is applied and the drain of the NMOS transistor Q17. The PMOS transistors Q20 and Q21 may be turned on in response to the non-inverted input signal VB of a low level, and thereby, may transfer the input driving voltage VDDL to the drain of the NMOS transistor Q17.

The second clamping circuit 54 described above may include at least two PMOS transistors, for example, PMOS transistors Q22 and Q23, which are connected in series. The PMOS transistors Q22 and Q23 have gates to which the inverted input signal VA is applied in common, and are connected in series between the terminal to which the constant voltage is applied and the drain of the NMOS transistor Q18. The PMOS transistors Q22 and Q23 may be turned on in response to the inverted input signal VA of a low level, and thereby, may transfer the input driving voltage VDDL to the drain of the NMOS transistor Q18.

As described above, in the embodiment of FIG. 1, the input circuit 20 is configured using the NMOS transistors Q17 and Q18 which are low power transistors. Since the input signals VA and VB of the low voltage range, which satisfy the operation range of the NMOS transistors Q17 and Q18, are applied to the gates of the NMOS transistors Q17 and Q18, the NMOS transistors Q17 and Q18 may be operated by sufficient amounts of current. Therefore, the output circuit 10 may also have a normal output by the operation of the input circuit 20 which is operated by a sufficient amount of current satisfying the operation range thereof as described above, and may be operated at a high speed.

Thus, the high speed level shifter of FIG. 1 can be prevented from malfunctioning, and can be expected to have an effect to be capable of performing a high speed operation.

Also, in the high speed level shifter of FIG. 1, the voltage dropping of the connection circuit 30 may prevent the high-voltage output driving voltage VDDH of the high voltage range, which is applied to an output terminal, from directly exerting an influence on the input circuit 20 which is configured by low power transistors. Therefore, the low voltage transistors of the input circuit 20 may be prevented from being damaged by a high voltage.

Further, in the high speed level shifter of FIG. 1, the drain voltages of the low voltage transistors of the input circuit 20 may be protected by the clamping circuit 50. Hence, the high speed level shifter in accordance with the embodiment of the present disclosure may secure operational stability.

The embodiment of FIG. 1 is configured such that the NMOS transistors Q15 and Q16 of the connection circuit 30 are switched by the inverted input signal VA and the non-inverted input signal VB.

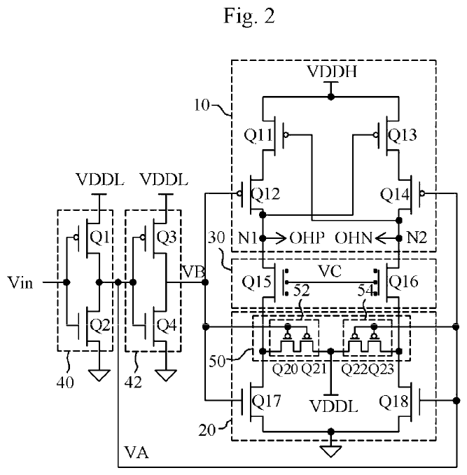

However, the connection circuit 30 may be configured such that turn-on of the NMOS transistors Q15 and Q16 is maintained by a constant voltage VC as illustrated in FIG. 2. FIG. 2 is different from FIG. 1 only in the configuration of the connection circuit 30 and the other configuration of FIG. 2 is the same as that of FIG. 1, and thus, repeated description thereof will be omitted.

In other words, the connection circuit 30 of FIG. 2 is embodied to be configured such that connection between an output terminal and the input circuit 20 is maintained by the constant voltage VC.

The constant voltage VC may have a level between the output driving voltage VDDH and the input driving voltage VDDL, and in particular, may have a medium level between the output driving voltage VDDH and the input driving voltage VDDL.

Alternatively, the constant voltage VC may have the input driving voltage VDDL according to a manufacturer's intention.

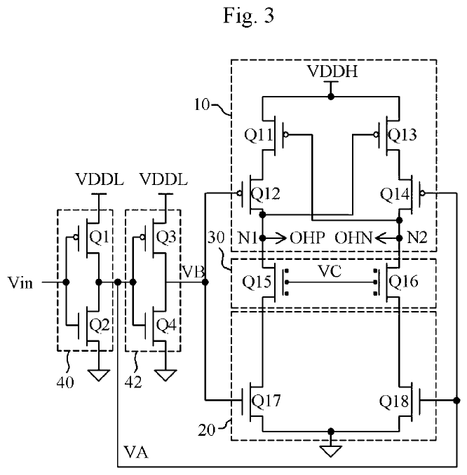

The embodiments of FIGS. 1 and 2 are embodied such that the clamping circuit 50 is included in the input circuit 20. However, according to a manufacturer's intention, an embodiment of the present disclosure may be embodied such that the configuration of the clamping circuit 50 is excluded from the input circuit 20 as illustrated in FIG. 3. FIG. 3 is different from FIG. 2 only in that the configuration of the clamping circuit 50 is excluded in the input circuit 20 and the other configuration of FIG. 3 is the same as that of FIG. 2, and thus, repeated description thereof will be omitted.

The high speed level shifter according to the embodiments of the present disclosure, embodied as illustrated in FIGS. 1 to 3, may prevent a malfunction and is capable of a high speed operation for outputting an output signal of a high voltage range, when an electronic device such as a micro control unit outputs the output signal of the high voltage range in response to an input signal of a low voltage range which has a logic level.

Also, in the high speed level shifter according to the embodiments of the present disclosure, embodied as illustrated in FIGS. 1 to 3, damage to a low voltage transistor configured in an input circuit may be prevented, and a drain voltage of the low voltage transistor may be protected. Therefore, the high speed level shifter according to the embodiments of the present disclosure may have improved reliability and secure operational stability.

What is claimed is:

1. A high speed level shifter comprising:
an output circuit configured to output an output signal of a high voltage range in response to an input signal of a low voltage range;
an input circuit configured to control output of the output signal in response to the input signal; and
a connection circuit connecting the output circuit and the input circuit,
wherein the output circuit is operated in the high voltage range,
wherein the input circuit is operated in the low voltage range, and
wherein the connection circuit drops a voltage applied to the input circuit from the output circuit.

2. The high speed level shifter according to claim 1, wherein the input circuit controls the output signal outputted through an output terminal of the output circuit, in response to the input signal.

3. The high speed level shifter according to claim 1, wherein the connection circuit selectively performs connection of the output circuit and the input circuit, in response to the input signal.

4. The high speed level shifter according to claim 1, wherein the connection circuit maintains connection of the output circuit and the input circuit by a constant voltage.

5. The high speed level shifter according to claim 4, wherein the connection circuit maintains connection of the output circuit and the input circuit by the constant voltage which has a level between an output driving voltage of the high voltage range and an input driving voltage of the low voltage range.

6. The high speed level shifter according to claim 5, wherein the connection circuit uses the input driving voltage of the low voltage range as the constant voltage.

7. The high speed level shifter according to claim 1, wherein
the output circuit includes a first output terminal and a second output terminal which are configured in parallel,
the output circuit outputs a first output signal through the first output terminal in response to a non-inverted input signal, and outputs a second output signal through the second output terminal in response to an inverted input signal,
the input circuit controls output of the first output signal of the first output terminal in response to the non-inverted input signal, and controls output of the second output signal of the second output terminal in response to the inverted input signal, and
the connection circuit drops the voltage applied to the input circuit from the first output terminal or the second output terminal.

8. The high speed level shifter according to claim 7, wherein the connection circuit drops the voltage such that the first output signal and the second output signal are applied on the input circuit with a level included in the low voltage range.

9. The high speed level shifter according to claim 8, wherein
the input circuit comprises a first low voltage transistor which operates in the low voltage range and selectively controls the first output terminal to a ground level by the non-inverted input signal of a gate thereof, and a second low voltage transistor which operates in the low voltage range and selectively controls the second output terminal to the ground level by the inverted input signal of a gate thereof,
the connection circuit comprises a first connection transistor which connects the first output terminal and the first low voltage transistor, and a second connection transistor which connects the second output terminal and the second low voltage transistor, and
a voltage applied to the input circuit from the first output terminal or the second output terminal is dropped by a voltage applied between a drain and a source of the first connection transistor or the second connection transistor.

10. The high speed level shifter according to claim 9, wherein the output circuit comprises a first high voltage transistor which operates in the high voltage range and selectively transfers the output driving voltage of the high voltage range to the first output terminal by the non-inverted input signal of a gate thereof, and a second high voltage transistor which operates in the high voltage range and selectively transfers the output driving voltage of the high voltage range to the second output terminal by the inverted input signal of a gate thereof.

11. The high speed level shifter according to claim 9, wherein the first connection transistor and the second connection transistor operate in a medium voltage range lower than the high voltage range and higher than the low voltage range.

12. The high speed level shifter according to claim 9, wherein
the input circuit further comprises a clamping circuit which is connected to drains of the first low voltage transistor and the second low voltage transistor; and
the clamping circuit clamps the drain of the first low voltage transistor or the second low voltage transistor which is turned off, to a constant voltage.

13. The high speed level shifter according to claim 12, wherein the clamping circuit comprises:
a first clamping circuit configured to provide the constant voltage to the drain of the first low voltage transistor in response to the non-inverted input signal when the first low voltage transistor is turned off; and
a second clamping circuit configured to provide the constant voltage to the drain of the second low voltage transistor in response to the inverted input signal when the second low voltage transistor is turned off.

14. The high speed level shifter according to claim 13, wherein each of the first clamping circuit and the second clamping circuit comprises a plurality of PMOS transistors which are connected in series and are the same.

15. The high speed level shifter according to claim 12, wherein the clamping circuit uses a input driving voltage of the low voltage range as the constant voltage.
